(19) United States
(12) Patent Application Publication
(10) Pub. No.: US 2026/0305313 A1
(43) Pub. Date: Oct. 1, 2026

(54) APPARATUS INCLUDING CELL CONTACT AND REDISTRIBUTION LAYER STRUCTURE

(71) Applicant: Micron Technology, Inc., Boise, ID (US)

(72) Inventors: Akira Kaneko, Hiroshima (JP); Naokazu Murata, Higashihiroshima-shi (JP); Keisuke Shimada, Higashihiroshima-shi (JP)

(21) Appl. No.: 19/574,000

(22) Filed: Mar. 20, 2026

Related U.S. Application Data
(60) Provisional application No. 63/778,676, filed on Mar. 27, 2025.

(51) Int. Cl. H10W 20/44; H10B 12/00; H10W 20/41; H10W 20/42; H10W 20/48

(52) U.S. Cl. CPC H10W 20/4441; H10B 12/315; H10B 12/318; H10B 12/34; H10B 12/482; H10W 20/422; H10W 20/435; H10W 20/4451; H10W 20/48; H10B 12/0335

(57) ABSTRACT

Some embodiments of the disclosure provide an apparatus comprising a cell contact-redistribution layer (RDL) structure in a memory device. The structure includes a cell contact that has a contact poly (polysilicon) coupled to an active region of a semiconductor substrate, a contact cobalt (cobalt silicide) on the contact poly, a barrier metal on the contact cobalt, and a contact metal on the barrier metal, located beneath the RDL. The entire top surface of the contact cobalt may be covered by the barrier metal. A side portion of the barrier metal may be lower than a top portion of the contact metal. This apparatus can effectively prevent cobalt oxidation and hence eliminate defects in the cell contact, enhancing quality and performance of memory devices.

### CROSS-REFERENCE TO RELATED APPLICATIONS

This application claims the filing benefit of U.S. Provisional Application No. 63/778,676, filed Mar. 27, 2025. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines arranged in rows and bit lines arranged in columns in a memory cell array. Each memory cell may include a capacitor for data storage and a transistor for accessing the capacitor. A memory cell capacitor may be coupled to either source or drain of an associated memory cell transistor formed in active regions of a semiconductor substrate, via a cell contact and a redistribution layer. A cell contact may be coupled at one end to either the source or drain region and at another end to a redistribution layer. The redistribution layer may then be coupled to the associated memory cell capacitor. The cell contact and the redistribution layer may thus serve to couple the cell capacitor to one of the source/drain regions in the semiconductor substrate. A bit line may be coupled to the other source/drain region.

### BRIEF DESCRIPTION OF THE DRAWINGS

FIGS. 1A and 1B depict an example configuration of at least part of a memory device in a plan view and a cross-sectional view, respectively, according to some embodiments of the disclosure.

FIGS. 2A-2B to 6A-6B depict example processes of forming at least part of a memory device in a plan view and a cross-sectional view according to some embodiments of the disclosure.

FIG. 7 depicts a schematic configuration of an example semiconductor system according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

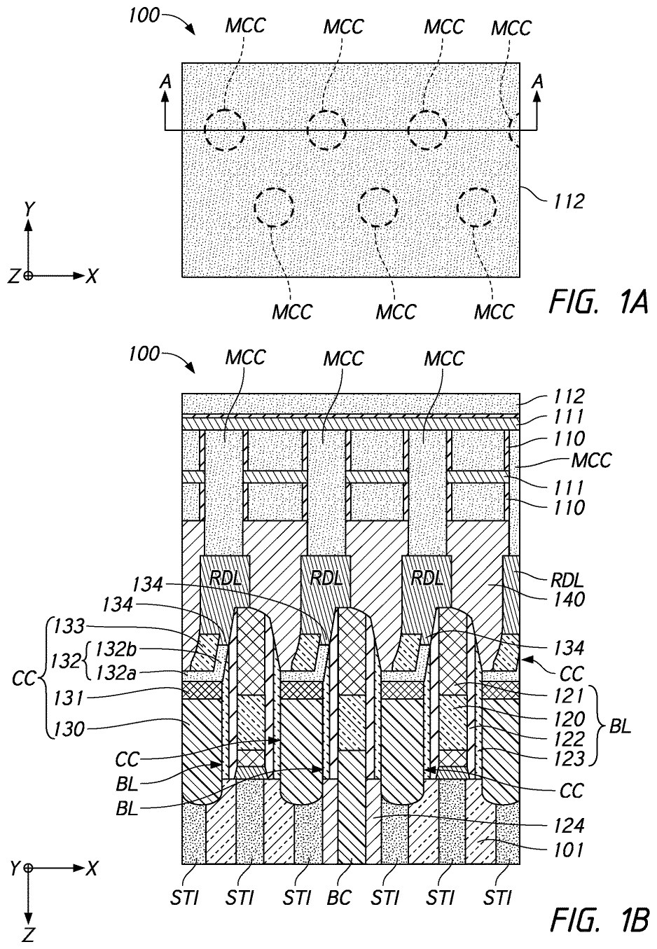

FIGS. 1A and 1B depict an example configuration of at least part of a memory device 100 in a plan view and a cross-sectional view, respectively, according to some embodiments of the disclosure. The cross-sectional view of FIG. 1B corresponds to line A-A in FIG. 1A. The memory device 100 may be a dynamic random-access memory (DRAM). The memory device 100 may be one example of a semiconductor device. The memory device 100 may be one example of an apparatus. The memory device 100 may include a memory cell array region and a peripheral region on a semiconductor substrate 101, such as a silicon substrate. The memory cell array region may include a plurality of memory cells arranged at intersections of word lines and bit lines. The memory cell array region may have a square shape, a rectangular shape, or the like in a plan view on the semiconductor substrate 101. The peripheral region may be provided adjacent to the memory cell array region. The peripheral region may be provided around the memory cell array region in the plan view on the semiconductor substrate.

The memory device 100 includes a plurality of memory cell capacitors MCC at least in a memory cell array region. The memory cell capacitors MCC may include a conductive material, such as titanium nitride (TiN). The depicted example configuration may include high-k films 110 adjacent to the memory cell capacitors MCC. The high-k films 110 may include a high-k dielectric material, such as hafnium oxide (HfO). The depicted example configuration may further include insulating layers 111. The insulating layers 111 may include an insulating material, such as silicon nitride (SiN). Another conductive layer 112 including a conductive material, such as TiN, may also be provided on the memory cell capacitors MCC and the neighboring structures. In some instances, additional insulating layers and/or conductive layers may be provided as appropriate. The memory cell capacitors MCC may be arranged at intersections of word lines (not separately depicted) and bit lines BL. The memory cell capacitors MCC may be arranged in matrix. Each memory cell capacitor MCC may form at least part of a memory cell to store data by accumulating electric charges therein and to be accessed via the associated word line and bit line during data write and read operations. Each memory cell capacitor MCC may include a vertical capacitor structure that extends in a vertical direction, which may be for example a Z-axis direction in the drawing. Bit lines BL (may also be referred to as digit lines or data lines) may be arranged in parallel with each other in a first horizontal direction, which may be for example an X-axis direction in the drawing, and each may extend in a second horizontal direction, which may be for example a Y-axis direction in the drawing, orthogonal (or substantially orthogonal within reasonable tolerances of fabrication, measurement, etc.) to the first horizontal direction. Word lines may be arranged in parallel with each other in the Y-axis direction and each may extend in the X-axis direction, intersecting with bit lines BL in the plan view (for example, in a plane along the X-axis direction and the Y-axis direction).

Each bit line BL includes a bit line structure, which includes at least a conductive part 120 The conductive part 120 may include a conductive material, such as tungsten (W). On the conductive part 120 is an insulating layer 121 including an insulating material, such as SiN. Furthermore, an insulating film 122 may be provided on side surfaces of the conductive part 120 and the insulating layer 121. The insulating film 122 may include an insulating material, such as silicon oxide (SiO). Still furthermore, another insulating film 123 may be provided on the insulating film 122. The insulating film 123 may include an insulating material, such as SiN, different from the insulating material of the insulating film 122. The insulating films 122 and 123 may also be part of the bit line structure. The insulating films 122 and 123 may be insulating spacers. The insulating films 122 and 123 may provide a sidewall of the bit line structure. In some instances, other elements, films, layers, or the like may be included in the bit line structure. The bit lines BL may be coupled to active regions (one of source/drain regions of a memory cell access transistor, for example) formed in the semiconductor substrate 101 via bit line contacts BC. Each bit line contact BC may include a conductive material, such as polycrystalline silicon or polysilicon (poly-Si). The bit line contact BC may be coupled to the conductive part 120 of the bit line structure and surrounded by part of the insulating films 122 and 123 and another insulating film 124 provided under the insulating films 122 and 123. The insulating film 124 may include an insulating material, such as SiN. The insulating film 124 may be part of the insulating spacer. The insulating film 124 may be part of the bit line structure. The memory device 100 may also include shallow trench isolations STI formed in the semiconductor substrate 101. The shallow trench isolations STI may include an insulating material, such as SiO.

The memory device 100 includes cell contacts CC and redistribution layers RDL arranged in matrix corresponding to the matrix of the memory cell capacitors MCC. The cell contacts CC have lower portions coupled to other active regions (another of the source/drain regions of the access transistor, for example) of the semiconductor substrate 101. The redistribution layers RDL have lower portions and upper portions coupled to the associated cell contacts CC and the associated memory cell capacitors MCC, respectively. The cell contacts CC and the redistributions layer RDL couple the associated memory cell capacitors MCC to the active regions of the semiconductor substrate 101. The redistribution layers RDL are arranged to contact at least upper portions of the cell contacts CC. The redistribution layers RDL may also contact upper portions of the bit lines BL adjacent to the cell contacts CC. The redistribution layers RDL may include a conductive material, such as W.

Each cell contact CC includes a cell contact structure, which includes a first contact part 130, a second contact part 131, a third contact part 132, and a fourth contact part 133. The first contact part 130 extends vertically (e.g., in the Z-axis direction in the drawing) into the semiconductor substrate 101, and is coupled to the active region formed in the semiconductor substrate 101 at a lower end. The first contact part 130 may include poly-Si. The first contact part 130 may also be referred to as a contact poly. The second contact part 131 is provided on a top potion of the first contact part 130 and may include cobalt (Co) or cobalt silicide (CoSi₂). The first and second contact parts 130 and 131 may form a contact plug, which couples the third and fourth contact parts 132 and 133 to the active region of the semiconductor substrate 101. The first contact part 130 and the second contact part 131 may be a lower (poly-Si) part and an upper (Co/CoSi₂) part of the contact plug, respectively. The third contact part 132 is provided on the second contact part 131. The third contact part 132 may include a conductive material, such as titanium (T) and TiN. The conductive material of the third contact part 132 may be a barrier metal. The barrier metal may be provided in a film form including a bottom portion and a side portion. The fourth contact part 133 is provided on the third contact part 132 and may include a conductive material, such as W, different from the conductive material of the third contact part 132. The fourth contact part 133 contacts the bottom and side portions of the third contact part 132. The third contact part 132 and the fourth contact part 133 may also be referred to as a barrier metal (or a barrier metal film) and a contact metal, respectively, of the cell contact CC. The barrier metal and the contact metal are coupled to the active region of the semiconductor substrate 101 via the contact plug. In some instances, the first and second contact parts 130 and 131 and the third and fourth contact parts 132 and 133 may be formed in a contact hole (not separately depicted) between adjacent bit line structures in that order, filling the contact hole. In some instances, other elements, films, layers, or the like may be included in the cell contact structure.

In the depicted example configuration, each cell contact CC has an entire top surface of the second contact part 131 covered by the third contact part 132. The third contact part (hereinafter referred to as the barrier metal) 132 includes a bottom part 132a and a side part 132b on the second contact part (hereinafter referred to as contact cobalt) 131. The bottom part 132a covers the entire top surface of the contact cobalt 131. More specifically, in the depicted example, the entire or substantially the entire top surface of the contact cobalt 131 is covered by the barrier metal 132 for protection. The bottom part 132a and the side part 132b of the barrier metal 132 at least partially surround bottom and side surfaces of the fourth contact part (hereinafter referred to as the contact metal) 133. The side part 132b of the barrier metal 132 is coupled to the redistribution layer RDL. The contact metal 133 is also coupled to the same redistribution layer RDL. The cell contact CC is hence coupled to the associated redistribution layer RDL.

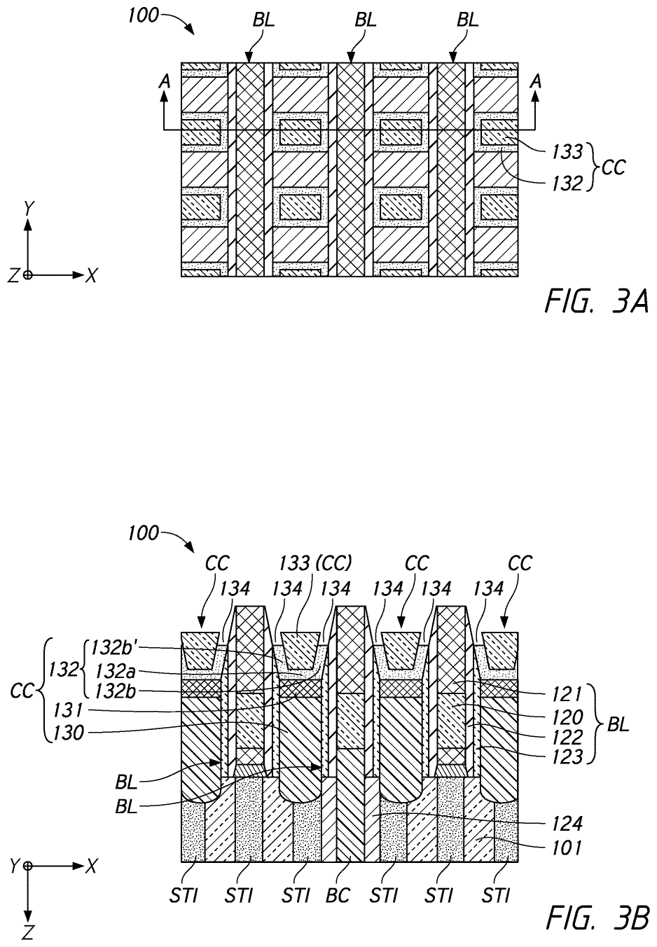

Furthermore, in the depicted example configuration, a top surface of the side part 132b of the barrier metal 132 is lower than a top surface of the contact metal 133. This provides a recess 134 (also see 134 in FIG. 3B, for example) of the barrier metal 132 between an upper portion of the contact metal 133 and the sidewall of the neighboring bit line/bit line structure BL. In some instances, the depicted bit line structure may have the sidewall slanted, and the upper portion of the contact metal 133 may have a slanted side surface in parallel to the slanted sidewall of the bit line structure. The barrier metal recess 134 formed between the upper portion of the contact metal 133 and the sidewall of the bit line structure thus may have a slanted shape. Accordingly, each cell contact CC includes the barrier metal recess 134 on the side part 132b of the barrier metal 132. The barrier metal recess 134 is filled with a conductive material of the redistribution layer RDL. As one example, the contact metal 133 of the cell contact CC includes tungsten (W), the barrier metal 132 of the cell contact CC includes titanium (Ti) or titanium nitride (TiN), and the redistribution layer RDL includes tungsten (W) as the conducive material. The side part 132b of the barrier metal 132 under the barrier metal recess 134 is lower than the top part of the contact metal 133.

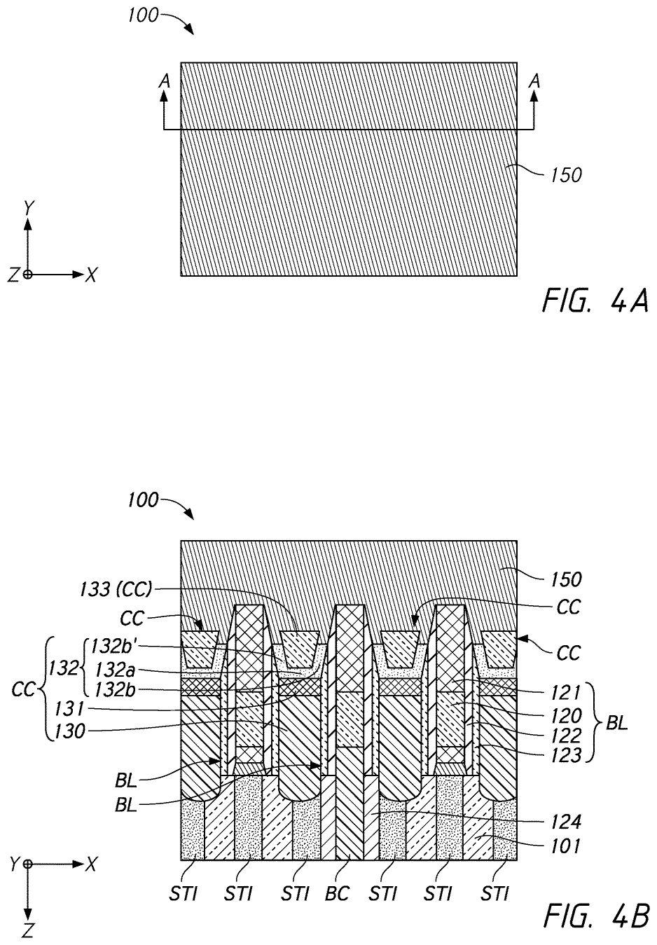

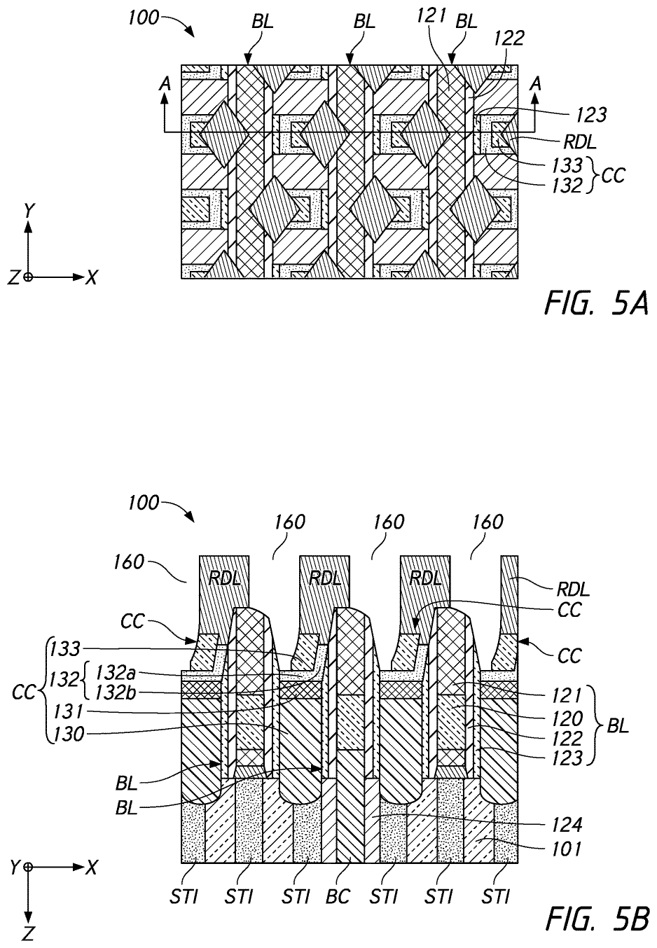

Still furthermore, in the depicted example configuration, an insulating member 140 is provided adjacent to the RDL and the contact metal 133 of the cell contact CC. The insulating member 140 includes a bottom part on the bottom part 132a of the barrier metal 132 of the cell contact CC. The insulating member 140 is adjacent to the redistribution layer RDL and the contact metal 133 of the cell contact CC on one side and to the bit line structure BL on an opposite side. The insulating member 140 fills a space between the redistribution layer RDL/contact metal 133 and the bit line structure BL. The insulating member 140 covers the redistribution layer RDL. The insulating member 140 may be an insulating layer. The insulating member 140 includes an insulating material, such as SiN. In some instances, the space between the redistribution layer RDL/contact metal 133 and the neighboring bit line structure BL may be formed by partially removing the redistribution layer RDL, the contact metal 133, and the bit line structure BL through, for example, an etching process. This may create a hole (see 160 in FIG. 5B, for example) which is filled with the insulating member 140. In some instances, before the etching process, the cell contact CC may have another side part (see 132b′ in FIGS. 3B and 4B, for example) of the barrier metal 132 on the opposite side from the side part 132b. During the etching process, this opposite side part may be fully removed so that, as illustrated in FIG. 1B, no side part remains on the bottom part 132a on the opposite side of the side part 132b. In other instances, the opposite side part may be partially removed, leaving a portion thereof on the bottom part 132a. In either case, the bottom part 132a remains intact, covering the top surface of the contact cobalt 131.

If the bottom part 132a of the barrier metal 132 is etched and the contact cobalt 131 is damaged during the etching process, oxidation of the contact cobalt 131 might occur, leading to a high-resistance single-bit defect. On the other hand, the configuration according to the present embodiments effectively protects the contact cobalt 131 from oxidation and prevents in the cell contact CC defects due to cobalt oxidation. The present embodiments can thus achieve memory devices of higher quality and performance.

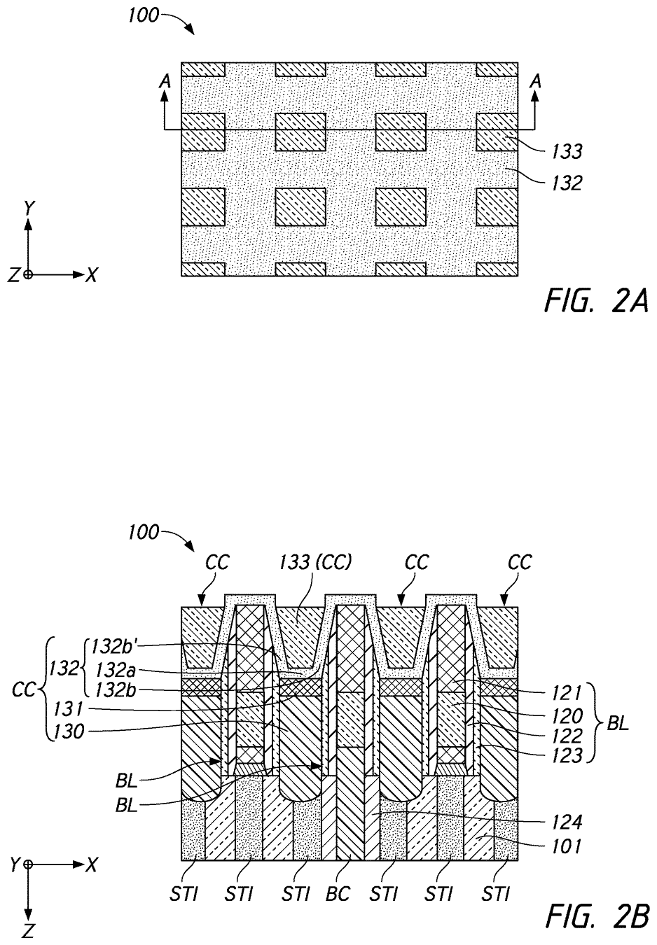

FIGS. 2A-2B to 6A-6B depict example processes of forming at least part of the memory device 100 including the cell contacts CC and the redistribution layers RDL in a plan view and a cross-sectional view according to some embodiments of the disclosure. FIGS. 2A-6A depict the processes in the plan view. The cross-sectional views in FIGS. 2B-6B correspond to line A-A in FIGS. 2A-6A. The memory device 100 of these figures corresponds to the memory device 100 of FIGS. 1A-1B. An example method to form at least part of a memory device according to some embodiments of the disclosure may include the processes described below.

First, as shown in FIGS. 2A and 2B, a part of the memory device 100 is formed, including, for example, the shallow trench isolations STI and the bit line contacts BC in the semiconductor substrate 101 and the bit lines/bit line structures BL (hereinafter referred to as bit line structures BL) on the semiconductor substrate 101. Between the neighboring bit line structures BL are cell contacts CC each extending vertically into the semiconductor substrate 101. The cell contacts CC may be provided in cell contact holes (not separately depicted) formed between the bit line structures BL. The cell contact holes may be formed by conventional methods, such as photolithography and etching, as appropriate. Each cell contact CC includes the first contact part (contact poly) 130, the second contact part (contact cobalt) 131, the third contact part (barrier metal) 132, and the fourth contact part (contact metal) 133 layered in that order in the contact hole. For example, the contact poly 130 and the contact cobalt 131 are first formed by depositing poly-Si and Co or CoSi₂ to the lower portion of the cell contact hole and etching to remove excess materials. More specifically, as one example, the material (poly-Si) of the contact poly 130 may be deposited, and a portion of the contact poly 130 may be removed by etching so that a remaining portion of the contact poly 130 is buried in the cell contact hole, followed by deposition of the material (Co or CoSi₂) of the contact cobalt 131 on the contact poly 130 in the cell contact hole. Subsequently, the barrier metal 132 and the contact metal 133 are provided on the contact cobalt 131 in the upper portion of the cell contact hole. More specifically, as one example, the barrier metal 132 (such as Ti or TiN) is first provided in a film shape on a top surface of the contact cobalt 131 and a side surface of the cell contact hole as well as on a top portion of the bit line structure BL. The contact metal 133 (such as W) is then provided on the barrier metal 132 and the top portion of the bit line structure BL, and the excess metal material is removed by, for example, polishing, such as chemical mechanical polishing (CMP). The formation of the cell contact structure may be performed by any conventional methods as appropriate. As described above with reference to FIGS. 1A and 1B, in the resultant cell contact structure, the entire top surface of the contact cobalt 131 is covered by the barrier metal 132. The barrier metal 132 includes the bottom part 132a and the side parts 132b and 132b′. The bottom part 132a is flat or substantially flat on the contact cobalt 131. The side parts 132b and 132b′ extend upwards from the bottom part 132a and are adjacent to the side wall of the bit line structure BL. In the depicted example, since at least the upper portion of the contact hole is formed to have the slanted side surfaces by removing part of the side walls of the bit line structure BL, the side parts 132b and 132b′ of the barrier metal 132 also have the slanted shape.

Next, as shown in FIGS. 3A and 3B, the barrier metal 132 and the contact metal 133 are partially removed by, for example, etching. During this process, the barrier metal 132 may be removed more than the contact metal 133 to lower the side parts 132b and 132b′ of the barrier metal 132 below the top surface of the contact metal 133. Etching may be performed using either dry etching or wet etching. Both dry etching and wet etching may be conducted under conditions that enable selective etching of the barrier metal 132. For example, an etchant with greater selectivity for the barrier metal 132 (such as Ti and TiN) than for the contact metal 133 (such as W) may be used. Additionally, the etchant may exhibit higher selectivity for the barrier metal 132 than for the bit line structure BL (such as SiN and SiO). As one example, in the case of dry etching, the etchant may include chlorine (Cl)-based gases, such as Cl₂ and BCl₃. For wet etching, the etchant may include sulfuric acid (H₂SO₄). During the wet etching process, H₂SO₄ may be used at a high temperature, such as around 90 degrees Celsius. This is higher than the regular process temperature which ranges from room temperature to about 60 degrees Celsius. The high temperature sulfuric acid process or hot sulfuric acid achieves greater selectivity for titanium. Other conditions, such as etch process time, may also be appropriately determined such that the side parts 132b and 132b′ of the barrier metal 132 becomes sufficiently lower than the contact metal 133. In some instances, by appropriately adjusting the etching conditions, at least the side part 132b′ of the barrier metal 132 may be fully or substantially fully removed, leaving only the bottom part 132a of the barrier metal 132 and the side part 132b on the bottom part 132a. In either case, the removal of at least portion of the side parts 132b and 132b′ of the barrier metal 132 forms the recess 134 between the lowered side parts 132b and 132b′ of the barrier metal 132 and the top part of the contact metal 133. The lowered side parts 132b and 132b′ of the barrier metal 132 may help in avoiding damages to the contact cobalt 131 during the later process of patterning the redistribution layer RDL and the cell contact CC (see FIGS. 5A-5B).

Subsequently, as shown in FIGS. 4A and 4B, a conductive layer 150 is provided on the contact metal 133 and the side parts 132b and 132b′ of the barrier metal 132 of the cell contact CC and on the bit line structures BL. Conventional methods, such as sputtering or physical vapor deposition, may be used as appropriate. The conductive layer 150 may include a conductive material, such as tungsten (W). The conductive material of the conductive layer 150 fills the barrier metal recess 134.

As shown in FIGS. 5A and 5B, the redistribution layer RDL is then formed by removing part of the conductive layer 150 using, for example, an etching process. During this process, part of the bit line structure BL and part of the barrier metal 132 and contact metal 133 of the cell contact CC are also removed, creating a hole 160. More specifically, a portion of the top part of the bit line structure BL, a portion of the side wall of the bit line structure BL, a portion of the contact metal 133 of the cell contact CC, and the side part 132b′ of the barrier metal 132 of the cell contact CC are removed, while the bottom part 132a of the barrier metal 132 remains unetched or at least intact to the extent that it covers the top surface of the contact cobalt 131. The hole 160 thus created extends vertically through the conductive layer 150 (forming the redistribution layer RDL) and the contact metal 133 but does not penetrate the bottom part 132a of the barrier metal 132. The hole 160 stops at the bottom part 132a of the barrier metal 132 and does not reach the contact cobalt 131 under the barrier metal 132.

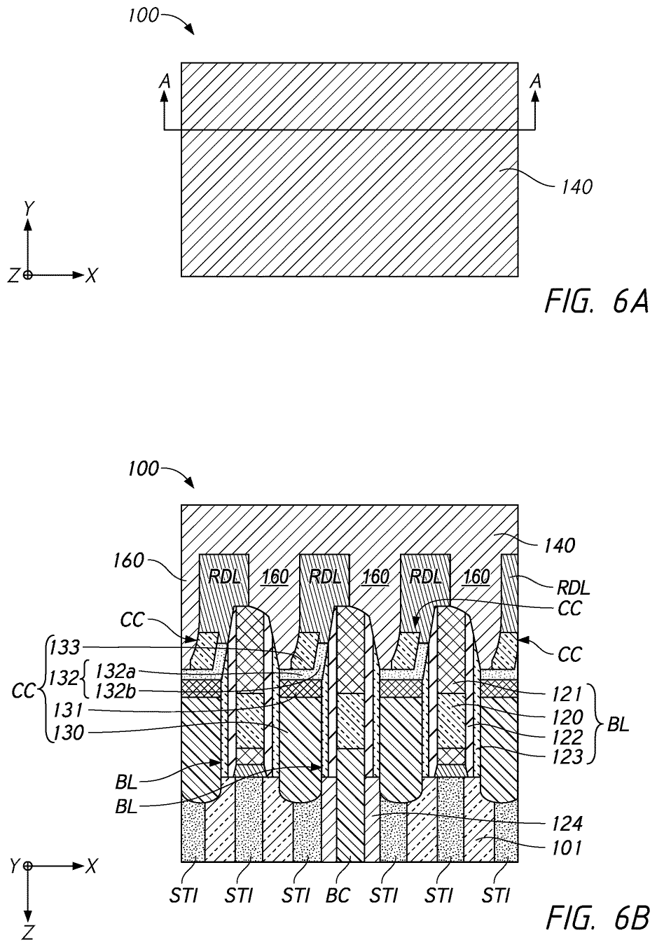

As shown in FIGS. 6A and 6B, an insulating layer 140 is provided to fill the hole 160 and cover the redistribution layers RDL. The insulating layer 140 may include an insulating material, such as SiN. Because the hole 160 does not reach the contact cobalt 131, the insulating layer 140 also does not reach the contact cobalt 131.

Following the above process, as shown in FIGS. 1A and 1B, the memory cell capacitors MCC are formed on the corresponding redistribution layers RDL. Any conventional methods may be used to form the memory cell capacitors MCC and their surrounding structures as appropriate.

As the size of a memory device decreases, the size of the cell contact and redistribution layer structure between the semiconductor substrate and the memory cell capacitor also becomes smaller. This, in turn, tightens the process margin for redistribution layer shorts. For example, if the etching time of a conductive layer used to form a redistribution layer is extended to mitigate redistribution layer shorts, etching may reach a contact cobalt layer (such as CoSi₂) of the contact cell beneath the redistribution layer, potentially damaging the contact cobalt layer. This may lead to oxidation of the contact cobalt layer, resulting in a high-resistance single-bit defect. To prevent such over-etching which could damage the contact cobalt layer while addressing redistribution layer shorting concern, the present embodiments involve the partial removal of the barrier metal (e.g., Ti or TiN) and contact metal (e.g., W) of the cell contact. This process ensures that the side part of the barrier metal is lower than the top part of the contact metal (see 132/132b/132b′ and 133 of CC in FIGS. 3A-3B) after the deposition and polishing of the conductive materials of the barrier metal and contact metal (see 132 and 133 in FIGS. 2A-2B) but before the deposition of the conductive layer (see 150 in FIGS. 4A-4B) and the formation/shaping of the redistribution layer and cell contact (see RDL and CC in FIGS. 5A-5B). Once at least one of the side portions of the barrier metal is sufficiently lowered below the contact metal (or possibly fully removed), the redistribution layer and the contact metal and barrier metal of the cell contact do not need to be etched as deeply in the subsequent process. This effectively prevents etching of the underlying contact cobalt layer in the cell contact. Accordingly, the present embodiments achieve the memory device, which effectively eliminates defects in the cell contact caused by cobalt oxidation due to etching of the contact cobalt layer (see 131 and CC in FIGS. 1A-1B).

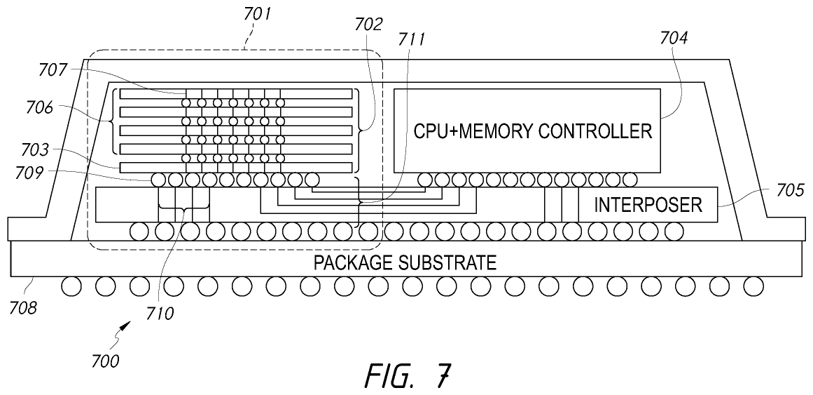

FIG. 7 depicts a schematic configuration of an example semiconductor system 700 according to some embodiments of the disclosure. The semiconductor system 700 includes a semiconductor memory device 701 in an embodiment of the disclosure. In some embodiments of the disclosure, the semiconductor memory device 701 may include the memory device 100 of FIGS. 1A-1B. The semiconductor system 700 may also include a central processing unit (CPU) and memory controller 704, which may be a controller chip, on an interposer 705 on a package substrate 708. The interposer 705 may include one or more power lines 710 which may supply power supply voltage from the package substrate 708. The interposer 705 may include a plurality of channels 711 that may interconnect the CPU and memory controller 704 and the semiconductor memory device 701. The semiconductor memory device 701 may be a DRAM. The memory controller 704 may provide a clock signal, a command signal, and may further transmit and receive data signals. The plurality of channels 711 may transmit the data signals between the memory controller and the memory device 701.

The semiconductor memory device 701 may include a plurality of dies (or chips) 702 including at least one interface (IF) die (or chip) 703 and a plurality of memory core dies (or chips) 706 stacked with each other. A number of the memory core dies 706 may not be limited to four as in the illustrated example, and may be more or fewer as appropriate. Each of the memory core dies 706 may include a plurality of memory cells and circuitries accessing the memory cells. For example, the memory cells may be DRAM cells. The memory cells may be arranged in array. The semiconductor memory device 701 may include conductive vias 707 which couple the IF die 703 and the memory core dies 706 by penetrating the IF die 703 and the memory core dies 706. The IF die 703 may be coupled to the interposer 705 via interconnects 709. For example, the interconnects 709 may be microbumps having bump pitches of less than about or less than one hundred micrometers and exposed on an outside of the IF die 703. A portion of each of the interconnects 709 may be coupled to the one or more power lines 710. Another portion of each of the interconnects 709 may be coupled to one or more of the channels 711.

In the above descriptions, DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising a cell contact coupled to a memory cell capacitor via a redistribution layer (RDL), the cell contact including:
a contact plug coupled to an active region formed in a semiconductor substrate;
a barrier metal on the contact plug; and
a contact metal on the barrier metal and coupled to the RDL, wherein
the contact plug includes:
a lower part coupled to the active region of the semiconductor substrate; and
an upper part coupled to the barrier metal, and
an entire top surface of the upper part of the contact plug is covered by the barrier metal.

2. The apparatus according to claim 1, wherein the barrier metal includes a bottom part configured to cover the entire top surface of the upper part of the contact plug.

3. The apparatus according to claim 2, wherein the barrier metal includes a side part on the bottom part, coupled to the RDL.

4. The apparatus according to claim 3, wherein the side part of the barrier metal and the contact metal are coupled to the RDL.

5. The apparatus according to claim 4, wherein the cell contact further includes a barrier metal recess on the side part of the barrier metal, the barrier metal recess filled with a conductive material of the RDL.

6. The apparatus according to claim 5, wherein the contact metal of the cell contact includes tungsten, the barrier metal of the cell contact includes titanium or titanium nitride, and the RDL includes tungsten as the conductive material.

7. The apparatus according to claim 5, wherein the side part of the barrier metal under the barrier metal recess is lower than a top part of the contact metal.

8. The apparatus according to claim 2, further comprising an insulating member adjacent to the RDL and the contact metal of the cell contact, wherein the insulating member includes a bottom part on the bottom part of the barrier metal of the cell contact.

9. The apparatus according to claim 8, wherein the insulating member is adjacent to the RDL and the contact metal of the cell contact on one side and to a bit line structure on an opposite side.

10. The apparatus according to claim 9, wherein the insulating member fills a space between the RDL and the bit line structure.

11. The apparatus according to claim 8, wherein the insulating member includes silicon nitride.

12. The apparatus according to claim 1, wherein the contact metal includes tungsten, the barrier metal includes titanium or titanium nitride, and the RDL includes tungsten.

13. The apparatus according to claim 1, wherein the lower part of the contact plug includes polysilicon, and the upper part of the contact plug includes cobalt or cobalt silicide.

14. An apparatus, comprising:
a first bit line structure and a second bit line structure;
a cell contact between the first bit line structure and the second bit line structure; and
a redistribution layer (RDL) on the first bit line structure and the cell contact; and
an insulating material between the second bit line structure on one side and the cell contact and RDL on another side, wherein
the cell contact includes:
a first contact part on an active region formed in a semiconductor substrate and including polysilicon;
a second contact part on the first contact part and including cobalt or cobalt silicide;
a third contact part on the second contact part and including a first conductive material, the third contact part is configured to cover an entire top surface of the second contact part, the insulating material is on the third contact part; and
a fourth contact part on the third contact part under the RDL and including a second conductive material different from the second conductive material.

15. The apparatus according to claim 14, wherein the third contact part includes a bottom portion and a side portion, the bottom portion covers the top surface of the second contact part between the first bit line structure and the second bit line structure, and the side portion is adjacent to the first bit line structure.

16. The apparatus according to claim 15, wherein the side portion of the third contact part is lower than a top portion of the fourth contact part.

17. The apparatus according to claim 15, wherein the cell contact includes a recess on the side portion of the third contact part, the recess filled with part of the RDL.

18. The apparatus according to claim 15, wherein the insulating material is on the bottom portion of the third contact part.

19. An apparatus, comprising:
a cell contact including:
a polysilicon portion;
a cobalt portion on the polysilicon portion;
a titanium portion on the cobalt portion; and
a tungsten portion on the titanium portion, wherein
the cobalt portion is covered by the titanium portion, and a side part of the titanium portion is lower than a top part of the tungsten portion; and
a nitride portion adjacent to the cell contact, wherein the nitride portion stops at the titanium portion and does not contact the cobalt portion under the titanium portion.

20. The apparatus according to claim 19, wherein the polysilicon portion includes polysilicon, the cobalt portion includes cobalt or cobalt silicide, the titanium portion includes titanium or titanium nitride, the tungsten portion includes tungsten, and the nitride portion includes silicon nitride.
